(19) United States
(12) Patent Application Publication
(10) Pub. No.: US 2026/0163581 A1
(43) Pub. Date: Jun. 11, 2026

(54) ASYNCHRONOUS SAR LOGIC

(71) Applicant: Vitalthings UWB AS, KVITESEID (NO)

(72) Inventors: Jørgen Andreas MICHAELSEN, Trondheim (NO); Håkon André HJORTLAND, Trondheim (NO)

(73) Assignee: Vitalthings UWB AS, Trondheim (NO)

(21) Appl. No.: 19/126,182

(22) PCT Filed: Oct. 25, 2023
(86) PCT No.: PCT/EP2023/079816

§ 371 Date: Apr. 30, 2025

(30) Foreign Application Priority Data
Nov. 2, 2022 (GB) 2216316.6

(51) Int. Cl. H03M 1/38

(52) U.S. Cl. CPC H03M 1/38

(57) ABSTRACT

A circuit for detecting metastability in an asynchronous successive approximation register analogue to digital converter; wherein a two-output comparator is arranged to receive first and second input signals, compare the signals, and drive one of the first and second comparison signals to a set state based on the comparison. A first output terminal is in a set state when the first comparison signal is in a set state. A second output terminal is in a set state when the second comparison signal is in a set state. If a predetermined duration passes after the start of the comparison and if the comparison signals are both in the reset state, control logic outputs a set state at both output terminals. This allows metastability of a comparator to be detected in an asynchronous SAR ADC. The control logic can effectively time out the comparison if it reaches the predetermined duration.

### BACKGROUND OF THE INVENTION

The present invention relates to a system and method of detecting metastability in an asynchronous successive approximation register (SAR) circuit.

SAR control logic is an important part of SAR Analogue to Digital Converters (ADCs). SAR logic can be synchronous or asynchronous. Synchronous SARs are clocked with a regular clock signal such that comparisons are made at defined time points, and equally there is a defined time period for the comparator to make a comparison and output a decision. Asynchronous SARs on the other hand are not clocked with a regular clock signal. Instead, the asynchronous SAR waits for a comparator decision to be made and then moves on to the next comparison. The decision times (comparisons) in an asynchronous SAR are therefore not made at regular time intervals. In SAR ADCs, the comparator decision time can be of concern, especially in high speed ADCs. If the comparator is not able to decide in the time allocated to the decision, e.g. because the effective input voltage is too small, the comparator is said to be in a metastable (MS) state.

Metastability usually results in large errors in ADC output. There are known approaches to handle this in synchronous SAR logic. The present invention aims to provide an approach to metastability for asynchronous SAR ADCs.

### SUMMARY OF THE INVENTION

According to a first aspect of the invention, there is provided a circuit for detecting metastability in an asynchronous successive approximation register analogue to digital converter; the circuit comprising:
a two-output comparator;
control logic;
a first output terminal; and
a second output terminal;
wherein the two-output comparator is arranged to receive first and second input signals;
wherein the two-output comparator is arranged to:
   receive a trigger signal from the control logic;
   based on the receipt of the trigger signal:
      set a first comparison signal and a second comparison signal to a reset state;
      compare the first input signal with the second input signal; and
      drive one of the first and second comparison signals to a set state based on the comparison;
wherein the control logic is configured such that:
   the first output terminal is in a set state when the first comparison signal is in a set state;
   the second output terminal is in a set state when the second comparison signal is in a set state; and
   if a predetermined duration passes after the start of the comparison by the two-output comparator and if the first comparison signal and the second comparison signal are both in the reset state, the control logic outputs a set state at both the first output terminal and the second output terminal.

According to a second aspect of the invention, there is provided a method of detecting metastability in an asynchronous successive approximation register analogue to digital converter; the method comprising:
receiving, at a two-input comparator, a first input signal and a second input signal,
receiving, at the two-input comparator, a trigger signal;
based on the trigger signal:
   setting a first comparison signal and a second comparison signal to a reset state;
   comparing the first input signal and the second input signal; and
   driving one of the first and second comparison signals to a set state based on the comparison;
      the method further comprising:
outputting a set state at a first output terminal when the first comparison signal is in a set state;
outputting a set state at a second output terminal when the second comparison signal is in a set state; and
outputting a set state at the first output terminal and the second output terminal if a predetermined duration passes after starting the comparison and if the first comparison signal and the second comparison signal are both in the reset state.

Thus it will be seen by those skilled in the art that, in accordance with the invention, metastability of a comparator can be detected in an asynchronous successive approximation register analogue to digital converter. By providing control logic that monitors a predetermined duration after the start of the comparison, the control logic can effectively time out the comparison if it reaches the predetermined duration. In other words, the control logic can override the comparator output and instead provide a defined output indicative of metastability. For the two-output comparator, the two outputs start off in a reset state (e.g. a low output signal). A successful comparison results in one of the outputs being changed to a set state (e.g. a high output signal) while the other output remains in the reset state (e.g. low output signal). Thus the normal outputs of the two-output comparator are: both outputs in reset state when no decision has yet been reached, or one output set and the other output reset once a decision has been made (with the decision reflecting which output is set and which is reset). The control logic described above adds a fourth output result in which both outputs are in a set state and which indicates that the predetermined duration elapsed before a decision was reached, i.e. that the comparator was in a metastable state.

The circuit may be configured to output a dedicated signal indicating that the comparator is in a metastable state such that external components connected to the circuit may be made immediately aware of the metastability condition as soon as it is determined. This may be particularly beneficial if the circuit is connected to a digital to analogue converter in a SAR ADC, as the dedicated output signal may be used to indicate to the SAR ADC that the first input signal and the second input signal are close in value.

In such a SAR ADC, the input voltage (the voltage being converted to digital) and the trial voltage (the present value of the interim voltage being successively determined by the SAR through successive conversion cycles) are compared by a comparator to determine whether the input voltage is higher or lower than the trial voltage of the present conversion cycle. When these two voltages are very close in value, the comparator may take a long time to reach a comparison decision and generate a suitable comparison output and thus may be considered to be in a metastable state. There are two main advantages to detecting this metastable state. Firstly, in an asynchronous SAR, the long comparison time adds to the overall time for a full ADC conversion and thus can easily exceed the conversion time expected by subsequent processing circuits. Secondly, when the two comparator inputs are sufficiently close, no further conversion cycles may be necessary as the trial voltage has already matched the input voltage to at least the accuracy possible by a complete set of conversion cycles, i.e. the difference between the input voltage and the trial voltage is less than one least significant bit of the SAR ADC. Therefore the dedicated signal indicating that the comparator is in a metastable state may be used by the SAR ADC to determine the state of one or more bits of the SAR ADC without delay (as the final digital output value is effectively already known), as will be discussed in more detail below. Thus, in some embodiments, if the control logic outputs a set state on both the first output terminal and the second output terminal, the circuit may be configured to output a signal representative of the two-output comparator being in a metastable state.

In some embodiments, the control logic may be configured to provide the trigger signal to the two-output comparator based on the two-output comparator driving one of the first and second comparison signals to a set state. The control logic may therefore be configured to receive the first comparison signal and the second comparison signal from the two-output comparator, and to output the trigger signal to the two-output comparator based on the states (set or reset) of the first and second comparison signals.

The two-output comparator may then perform a subsequent comparison of the first and second input signals following receipt of the new trigger signal. In this way, each time the two-output comparator performs a comparison of the first and second input signals, comparison signals may be provided to the control logic, causing a further subsequent trigger signal to be provided to the comparator, causing it to perform a further comparison. This means that the circuit may effectively be self-clocked. In this way the circuit does not need to rely on an external clock source, i.e. it is asynchronous, with each cycle being triggered by the output of the previous cycle. As the defined metastability state is also an output state of the circuit, it also results in a new trigger signal to the comparator, causing a new comparison. In this way, the circuit can provide a sequence of pairs of outputs at the first and second output terminals, each pair of outputs being associated with a respective trigger signal.

In some embodiments the trigger signal may trigger the two-output comparator to reset its outputs and commence a new comparison to set one of its two outputs. In such embodiments the trigger signal may comprise a rising edge or a falling edge that causes the two-output comparator to perform the reset and begin the new comparison. In other embodiments the trigger signal may comprise a reset part and an enable part. The reset part may cause the two-output comparator to reset its outputs and the enable part may enable the two-output comparator to perform a comparison and set one of its outputs appropriately. In such embodiments the comparator is held in a reset state during the reset part of the trigger signal and the comparator is released from the reset state and enabled to perform a comparison during the enable part of the trigger signal. In such embodiments it may be the magnitude of the trigger signal (rather than a timing edge of the trigger signal) that controls the operation of the comparator. In some examples the trigger signal may take one of two states (magnitudes), e.g. a high state (‘on’ on ‘1’) during the enable part and a low state (‘off’ or ‘0’) during the reset part. When the trigger signal comprises a reset part and an enable part, it will be appreciated that the comparison begins with the beginning of the enable part, i.e. it begins with the transition from the reset state to the enable state. Thus, the predetermined duration for the comparison is preferably measured from the beginning of the enable part of the trigger signal, i.e. from the time at which the comparator is released from the reset state.

The comparison signals generated by the comparator in response to a sequence of trigger signals may thus be used in the determination of a plurality of bit values in an SAR ADC, i.e. each time a bit is determined (or the circuit outputs a result indicative of the comparator being in a metastable state), a new comparison is initiated for the next bit.

In some embodiments, the control logic may comprise a first delay element, and the first delay element may be configured to delay the sending of the trigger signal to the two-output comparator by a second predetermined duration. The second predetermined duration may be selected to allow time for the first and/or second inputs to the comparator to stabilise before the comparator is triggered for the next comparison. This may be particularly advantageous in cases where at least one of the first or second input signals to the comparator is received from a digital to analogue converter (DAC), which may require a settling time after receiving an input code before a stable output is provided. The digital to analogue converter may be part of an SAR ADC and may generate the trial voltages in each conversion cycle of the SAR ADC. As the next trial voltage depends on the output of the present cycle, the second predetermined duration allows time for propagation of the result and processing by the DAC before the comparison of the next conversion cycle begins. It will be appreciated that where the trigger signal comprises a reset part and an enable part, both of these will be delayed by the first delay element. This means that the reset of the two-output comparator will be delayed after one of the outputs becomes set, which in turn means that the output state is held for the predetermined duration before the outputs are reset again. Once the reset part of the trigger signal propagates to the comparator, the outputs will be reset which in turn causes the trigger signal to commence the enable part which is propagated through the first delay element meaning that the two-output comparator remains in the reset state for at least the predetermined duration before commencing the next comparison.

In some embodiments, the first output terminal and the second output terminal may be connected to a plurality of bit logic circuits. The state of the first output terminal and the second output terminal may be used by each of the plurality of bit logic circuits to determine a bit value, e.g. a 0 or a 1, representative of the result of the comparison of the first and second input signals. Each bit logic circuit may therefore be configured to determine a bit value based on the state of the first and second output terminals. The plurality of bit logic circuits may be connected to the first output terminal and the second output terminal sequentially, e.g. using a switch or a demultiplexer. However, in some embodiments the plurality of bit logic circuits are all connected to the first output terminal and the second output terminal simultaneously (i.e. in parallel) so that they all receive the comparison output simultaneously. Further logic may be provided to enable each bit logic circuit in turn so that they process the comparison output sequentially.

For example, in some embodiments in which plurality of trigger signals are provided to the two-output comparator, each bit logic circuit may be configured to determine a respective bit value following receipt of a respective trigger signal at the two-output comparator.

The bit logic circuits may thus be configured to determine respective bit values in sequence, such that only a single bit logic circuit determines a respective bit value at any one time. The sequence may be advanced upon the generation of sequential trigger signals, such that for each trigger signal received by the comparator, a respective bit logic circuit may determine an associated bit value. Each bit logic circuit may therefore be arranged such that it determines a bit value only after its respective trigger signal has been output, causing each of the plurality of bit logic circuits to determine a respective bit value in sequence. In this way, a plurality of bit values may be determined, each bit value being representative of the relative magnitude of the first input signal and the second input signal at the time the respective trigger signal was received at the comparator.

It will be appreciated that in some embodiments there is one bit logic circuit for each bit of the SAR ADC and that in normal operation, one conversion cycle of the SAR ADC sets one output bit via one bit logic circuit. Each bit logic circuit may be operated in sequence from a most significant bit logic circuit through to a least significant bit logic circuit.

The bit values output by each of the bit logic circuits may be combined to generate a sequence of bit values representative of a digital code that may be used by a DAC to generate the first input signal or the second input signal.

Each bit logic circuit may be configured to indicate when its respective bit value has been determined. Thus, in some embodiments, when a bit logic circuit of the plurality of bit logic circuits determines a bit value, said bit logic circuit also outputs a completion signal indicating that a bit value has been determined for that bit logic circuit. The completion signal in a first bit logic circuit may be provided to a second bit logic circuit, and may be used to enable the second bit logic circuit to determine its respective bit value. In other words, the completion signal in a first bit logic circuit may be used to gate (or disable) the operation of the second bit logic circuit until after the first bit value has been determined.

As described above the bit logic circuits may be configured to determine respective bit values in sequence following receipt of a sequence of trigger signals at the comparator. In such embodiments, each bit logic circuit may also be prevented from determining its respective bit value until after a completion signal from the previous bit logic circuit is received. This may ensure that only a single bit logic circuit is active at any one time, and that the respective bit value determined by each bit logic circuit relates to the relative magnitude of the first input signal and the second input signal at the time the respective trigger signal was received. In some embodiments therefore, a completion signal may be provided from a bit logic circuit to the next bit logic circuit in sequence, and said next bit logic circuit may be configured to determine its respective bit value upon receipt of the completion signal.

The bit logic circuits may be configured to indicate when the comparator is in a metastable state. Thus, in some embodiments, if the control logic outputs a set state on both the first output terminal and the second output terminal following receipt of a trigger signal at the two-output comparator, the respective bit logic circuit (i.e. the currently enabled one) is configured to output a signal representative of the two-output comparator being in a metastable state. By providing a dedicated metastability output signal indicating that the comparator is in a metastable state, external components connected to the circuit may be made aware of the metastability condition as soon as it is determined. In addition, in some embodiments the metastability output signal may be specific to the first bit logic circuit in the sequence that experiences the metastability condition and therefore the metastability output signal is specific to that one bit logic circuit. In other words, in such embodiments only one bit logic circuit of the plurality of bit logic circuits outputs the metastability output signal. By providing this metastability output signal from a particular bit logic circuit, external components may be able to determine quickly the bit for which the comparator entered a metastable state. For example, each bit logic circuit may be able to provide a metastability output signal representative of the comparator being in a metastable state (e.g. by outputting a ‘1’ or ‘high’ signal) or a signal representative of the comparator not being in a metastable state (e.g. by outputting a ‘0’ or ‘low’ signal). An external component receiving such a signal from each of the bit logic circuits may therefore be able to identify the bit for which the comparator entered a metastable state as the bit associated with the single bit logic circuit that outputs a ‘1’ or ‘high’. It will of course be appreciated that in other embodiments a ‘0’ or ‘low’ may be indicative of metastability instead.

In some embodiments, if a bit logic circuit outputs a signal representative of the two-output comparator being in a metastable state, said signal may be provided to a global metastability detection circuit. The global metastability detection circuit may be arranged to track whether any of the bit logic circuits has indicated that the comparator is in a metastable state, and to provide a global metastability output signal indicating that the comparator is in a metastable state if so. This arrangement combines the ‘one hot’ encoding discussed above (in which only a single bit logic circuit outputs a metastability signal) into an accumulated signal that identifies the overall determination of a metastability event in any of the plurality of bit logic circuits.

The global metastability detection circuit may comprise a chain of OR gates. Each OR gate may be arranged to receive a first input from a respective bit logic circuit, and a second input from a previous OR gate in the chain of OR gates. The first input may be a metastability output signal from the bit logic circuit representative of whether the comparator is in a metastable state. The first OR gate in the chain may be arranged to receive an input from the first two bit logic circuits that provide such an output signal (e.g. the bit logic circuits representing the most significant bit and the next most significant bit). In this way, the output of each OR gate is dependent on the previous output, such that if a single OR gate of the global metastability detection circuit receives a signal from its respective bit logic circuit indicating that the comparator is in a metastable state, all of the later OR gates in sequence will receive a signal indicating that the comparator is in a metastable state. The signal from the final OR gate in sequence may be used to a provide a global metastability output signal, indicating that the comparator was determined to be in a metastable state at some point during the sequence.

In some embodiments, each OR gate of the global metastability detection circuit may be configured to output an accumulated metastability detection signal indicative of whether any bit logic circuit in the sequence up to that point has determined metastability in the comparator. In some embodiments each bit logic circuit is arranged to receive an accumulated metastability input and upon receipt of an accumulated metastability signal at the accumulated metastability input, the bit logic circuit may output a predetermined bit value and output a completion signal indicating that a bit value has been determined. This arrangement can be used to prevent bit logic circuits that have not yet determined bit values from going through the normal time-consuming comparison process for determining their bit values. Instead, as the comparator is known to be in a metastable state, the circuit is able to avoid further unnecessary processing in the event that metastability is detected.

Assuming that the metastable state was caused by the comparator inputs being very close together, the trial voltage input at one of the comparator inputs can be assumed to be the most accurate representation of the input voltage at the other of the comparator inputs. All further bit values can then be inferred without requiring further comparisons and therefore it is advantageous to cause each of the subsequent bit logic circuits to output a predetermined bit value to complete the output in a time efficient manner. For example, if the bit corresponding to the metastable state is determined to be a ‘1’, all subsequent bits may be determined to be ‘0’. Alternatively, if the bit corresponding to the metastable state is determined to be a ‘0’, all subsequent bits may be determined to be a ‘1’. An additional benefit of this is that the bit for which the comparator entered a metastable state can be identified easily from the output bit values. For example, if the predetermined value is ‘1’, the bit for which the comparator entered a metastable state may be identified by determining the last bit logic circuit (most significant bit) in sequence to output a ‘0’.

In some embodiments, a bit value may be determined to be high if the first output terminal is in a set state and the second output terminal is in a reset state. A bit value may be determined to be low if the first output terminal is in a reset state and the second output terminal is in a set state. Thus, each bit logic circuit may be configured to determine its respective bit value as high if the first output terminal is in a set state and the second output terminal is in a reset state, and to determine its respective bit value as low if the first output terminal is in a reset state and the second output terminal is in a set state.

In some embodiments, a bit value may be determined to be high if the first output terminal is in a set state and the second output terminal is in a set state. Thus, when the comparator is in a metastable state, the bit value is determined to be high. It will be appreciated that in other embodiments the circuit may be arranged to output the inverse of this determined bit value for convenience (for metastable output as well as for normal output). It will also be appreciated that in other embodiments the bit value may be determined to be low in the metastable state (or, again, the inverse of this bit value may be output for convenience).

In some embodiments, each of the bit logic circuits outputs its respective determined bit value to a digital to analogue converter. The digital to analogue converter may be part of the successive approximation register ADC. The DAC may use the received bit values in the generation of a DAC output signal that may be used as the first or second input signal of the two-output comparator. For example, the DAC may take the received bit values as the current best approximation of the input signal based on the conversion cycles that have completed so far. The DAC may then set or unset the next most significant bit that has not yet been tested and use this for the next comparison (whether to set or unset the next test bit depends on whether the SAR ADC is building up from a low value (e.g. all ‘0’s) or working down from a high value (e.g. all ‘1’s)). Thus, the comparator may be used to compare an input signal generated based on the bit values generated by the plurality of bit logic circuits with an input signal that is to be converted to a digital value. By comparing the signal from the DAC with the input signal to be converted, the circuit may generate successive bit values that may be used to update the signal from the DAC to better approximate the input signal with each conversion cycle.

In some embodiments the control logic may comprise a first OR gate arranged to receive the first comparison signal from the two-output comparator and a second OR gate arranged to receive the second comparison signal from the two-output comparator. The first OR gate and the second OR gate may be connected to the first and second output terminals, such that the state of the OR gate sets the state of the first and second output terminals. The first OR gate and the second OR gate may provide output signals to the first output terminal and the second output terminal respectively to set the state of the first output terminal and the second output terminal.

The control logic may further comprise a NOR gate arranged to receive an input signal from the output of the first OR gate and an input signal from the output of the second OR gate. The state of the NOR gate may determine the state of the trigger signal provided to the two-output comparator, such that the state of the NOR gate determines when the two-output comparator compares the first and second input signals.

As the NOR gate receives inputs from the first OR gate and the second OR gate, the state of the NOR gate may be updated based on the state of the first and/or second comparison signals set by the comparator. In some embodiments therefore, the output of the NOR gate may be provided to the two-output comparator as the trigger signal.

If one of the first comparison signal and the second comparison signal is driven to the set state, the NOR gate may be driven to the reset state, causing the trigger signal to begin a reset part of the trigger signal and thus to reset the comparator. In such embodiments the reset of the comparator causes the first and second comparison outputs to be driven to the reset state and thus causes the NOR gate to be driven to the set state. This causes the trigger signal to begin an enable part of the trigger signal and thus enables the next comparison of the comparator. In such embodiments, the control logic is configured to provide a new trigger signal (i.e. enabling a new comparison) to the two-output comparator in response to the two-output comparator driving one of the first and second comparison signals to a set state. The NOR gate may therefore be configured to provide successive trigger signals to the comparator in response to the comparator driving the first comparison signal or the second comparison signal to the set state based on a comparison of successive first input signals and second input signals.

In some embodiments, the control logic may also comprise an AND gate, arranged to receive the output of the NOR gate at a first input, and to receive a delayed output of the NOR gate at a second input, wherein the delayed output is received after the predetermined duration passes after receipt of the trigger signal. The output from the NOR gate to the AND gate may be delayed using a second delay element, arranged to delay the output of the NOR gate by the predetermined duration. Viewed alternatively, the AND gate has a first input and a second input, the first input and the second input each arranged to receive an output of the NOR gate, wherein the second input is delayed relative to the first input. The output of the NOR gate, may, in some embodiments, be delayed by a delay element defining a second predetermined duration. The delay element may be the same delay element arranged to delay the output of the trigger signal(s) from the control logic to the comparator described above. The second predetermined duration may therefore be the same predetermined duration applied to delay the output of the trigger signal(s) from the control logic to the comparator. The first input to the AND gate may also be delayed (with an additional delay before the second AND gate input). However, in some embodiments it is preferred that the first AND gate input is directly connected to the NOR gate output as this ensures a fast reset of the AND gate after the NOR gate input goes low. The output of the AND gate may be provided to an input of the first OR gate and to an input of the second OR gate. In this way, the first OR gate and the second OR gate may be caused to simultaneously set the state of the first output terminal and the second output terminal in response to a signal from the AND gate after the predetermined duration elapses after receipt of the trigger signal by the two-input comparator. This provides the override mechanism by timing out the comparator after the predetermined duration. The result is the simultaneous setting of the first output terminal and the second output terminal to the set state to indicate that the comparator is in a metastable state.

In some embodiments the output of the NOR gate is delayed by a delay element defining a second predetermined duration. It will be appreciated that this delay element may be the first delay element discussed above and the second predetermined duration is correspondingly the second predetermined duration also discussed above.

It will be appreciated that where this description refers to any logical gate such as an AND gate or a NOR gate it refers to any circuit that provides the logical functionality of that logic function. For example, it will be appreciated that most logic gates can (and often are) constructed from other gates for convenience, e.g. a NOR gate can be constructed from multiple NAND gates. For the purposes of this description, that collection of NAND gates is still considered to be a NOR gate as it provides NOR logic functionality. The same principle applies to all other logic gates.

Features of any aspect or embodiment described herein may, wherever appropriate, be applied to any other aspect or embodiment described herein. Where reference is made to different embodiments or sets of embodiments, it should be understood that these are not necessarily distinct but may overlap.

### BRIEF DESCRIPTION OF THE DRAWINGS

FIG. 1 is a schematic representation of a successive approximation register analogue to digital converter (SAR ADC) according to the prior art.

FIG. 2 is a schematic diagram of comparator circuit according to an embodiment of the present invention for use in an asynchronous SAR ADC;

FIG. 3 is a schematic diagram of a bit logic circuit according to an embodiment of the present invention for use in an asynchronous SAR ADC;

FIG. 4 is a schematic diagram of a metastability detection circuit according to an embodiment of the present invention;

FIG. 5 is a schematic representation of SAR logic according to an embodiment of the present invention; and

FIG. 6 is timing diagram illustrating the timing of signals in a comparator circuit and bit logic circuits according to the present invention.

### DETAILED DESCRIPTION

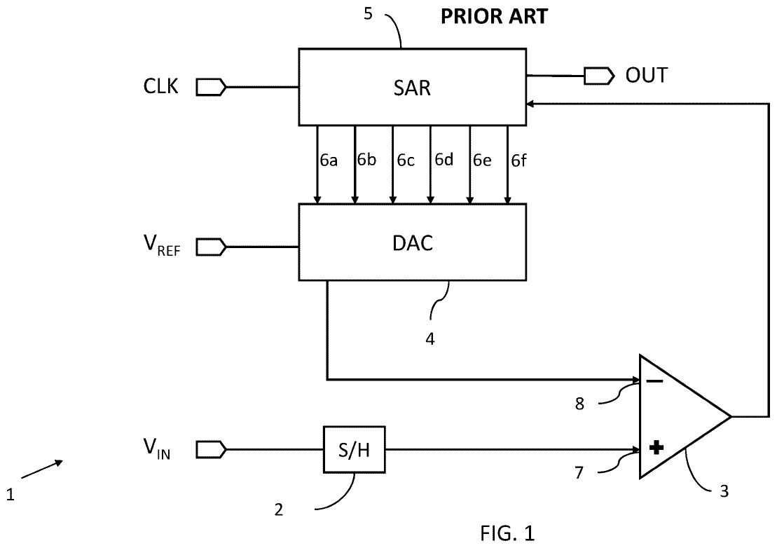

FIG. 1 shows a successive approximation register analogue to digital converter (SAR ADC) 1 according to the prior art.

The SAR ADC 1 includes a sample and hold circuit 2, arranged to receive an input voltage V_{IN} to be sampled, and to pass the sampled voltage to a comparator 3. The comparator 3 receives the sampled voltage V_{IN} at a positive terminal 7, and compares this to a voltage received at a negative terminal 8, generated by a digital to analogue convertor (DAC) 4 based on a reference voltage V_{REF}.

The comparator 3 amplifies the difference between the voltages received at the positive terminal 7 and the negative terminal 8. The comparator 3 is typically a high gain amplifier (e.g. a positive feedback amplifier) that quickly drives the output to a rail, whereupon the output remains stable. If the voltage at the positive terminal 7 is greater than the voltage at the negative terminal 8, the comparator 3 will output high. If the voltage at the positive terminal 7 is smaller than the voltage at the negative terminal 8, the comparator 3 will output low. The comparator outputs the result of the comparison to a successive approximation register (SAR) 5, based on which the SAR 5 generates a digital code for use by the DAC 4, selected to approximate the input voltage V_{IN}.

The digital code is made up of a plurality of bits 6a-6f, each bit having an associated weighting based on its position in the sequence. The bit with the highest weighting is the most significant bit (e.g. 6a), and represents the highest order place of a binary integer represented by the code. The bit with the lowest weighting is the least significant bit (e.g. 6f), and represents the binary ‘1’s place in the integer represented by the code. This code is provided to the DAC 4, which generates an analogue voltage based on the code and V_{REF} for use by the comparator 3.

In typical operation, the most significant bit is initially set to be high, e.g. equal to digital 1, with the rest of the bits set to be low, e.g. equal to digital 0, i.e. such that the code output to the DAC 4 in FIG. 1 reads 100000. The analogue equivalent of this code (e.g. V_{REF}/2) is generated by the DAC 4, and provided in the form of a voltage to the comparator 3, where it is compared to V_{IN}.

The comparator 3 amplifies the difference between V_{IN} and the voltage generated by the DAC, and provides an output signal to the SAR 5 indicating whether the voltage from the DAC 4 is greater or less than V_{IN}. If the analogue voltage is less than V_{IN}, the most significant bit, 6a, is left as a digital one, otherwise it is reset to being a digital zero. The SAR 5 then moves to the next most significant bit, 6b, which is then set to digital one (i.e. the code may be 010000 or 110000) and the process repeats, setting each bit to digital one or digital zero in turn, based on comparison of the voltage generated by the DAC 4 and the input voltage V_{IN}. This generates successive digital approximations of the input signal V_{IN} in the form of a code that becomes increasingly accurate with each successive bit processed by the SAR. Once all of the bits have been evaluated, a complete code ‘OUT’ being a digital representation of the input voltage V_{IN} is output by the SAR 5.

SAR ADCs of the kind shown in FIG. 1 typically start with the most significant bit and move along to the least significant bit, as described above. The logic controlling switching between successive bits can follow one of two approaches, employing either a ‘synchronous’ or ‘asynchronous’ mode of operation. In both modes, the SAR ADC is limited by the fact that comparators have a finite speed, and the time required to determine the difference between the input voltage and the reference voltage is strongly dependent on the difference between the two values. As the comparator relies on amplifying the difference between two input signals with a particular gain, there is an exponential relationship between the time required to determine the correct code and the difference between the input voltage and the target value, such that the comparator gets slower as the values being compared get closer. In the case that the input voltage and the reference voltage are near-identical, the time required for the comparator to output a result rises significantly, and in some cases an output cannot be provided within a useful duration (e.g. within a clock cycle of the SAR). This is known as metastability of the comparator. In such cases, the output of the comparator may not correctly reflect the relationship between the two comparator inputs and the SAR may set or unset a bit in the code incorrectly, leading to output errors.

In synchronous operation, a predetermined number of clock cycles (which may be just one clock cycle) is provided for the comparator to process each bit, i.e. to check each voltage generated by the DAC against the input voltage V_{IN}. As the successive bit analysis progresses according to the clock, the synchronous SAR will always finish its processing for a given input sample and thus will always provide an output value that is reasonably accurate (even if metastability occurred in one bit).

In asynchronous operation, a SAR ADC waits until the comparator has completed processing each bit before moving on to the next bit in sequence. This approach has the benefit of allowing more time to be spent on critical bits for which the comparator requires more time, but metastability can be a big issue as it can introduce a long delay in the processing time. If a value is read from the SAR ADC before it has finished processing a given sample, then large output errors can result. Although this issue can be mitigated to an extent by using a faster comparator, faster comparators have greater power requirements, as more gain is required. In addition, faster comparators may also generate more noise. Simply trying to speed up the determinations by the comparator is therefore not always viable.

Embodiments of the present invention provide an asynchronous SAR ADC in which a predetermined time period can be used to generate a metastable indicator at the output. The predetermined time period can be used to prevent the comparator from getting stuck for too long as well as providing an indication to onward processing that a particular ADC conversion resulted in metastability within the ADC. This allows other circuits to act appropriately on any metastable conversions. For example, by allowing metastability of the comparator to be identified. If the predetermined time period has elapsed with no output from the comparator, it can be assumed that the output of the DAC is at or very near the input voltage, and hence that the code corresponding to that DAC voltage at that time is an accurate representation of the input voltage V_{IN}.

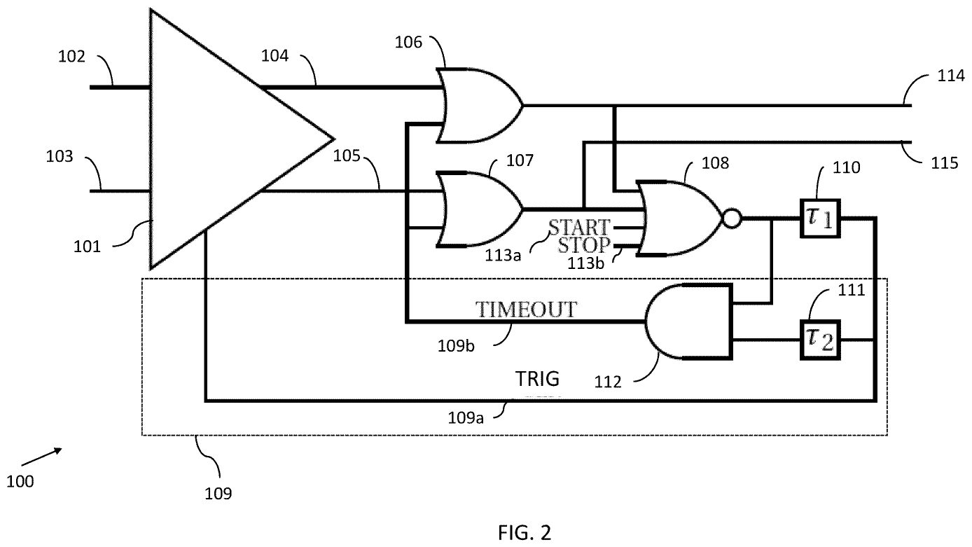

FIG. 2 shows a comparator circuit 100 according to an embodiment of the present invention for use in an asynchronous SAR ADC. The comparator circuit 100 is arranged to detect whether a comparator 101 of the circuit 100 is in a metastable state, and if so, to output a signal indicative of the metastable state.

The comparator 101 is arranged to receive a first input voltage from an external digital to analogue converter (not shown) at a first input terminal 102 and to receive a second input voltage at a second input terminal 103 from an analogue voltage source to be sampled by the SAR ADC.

The comparator 101 compares the magnitude of the voltages received at the first input terminal 102 and the second input terminal 103 and, based on the comparison, provides complementary outputs at a first comparator output 104 and a second comparator output 105. For example, if the magnitude of the voltage received at the first input terminal 102 is greater than the voltage received at the second input terminal 103 then the signal provided at the first comparator output 104 will be high (e.g. a digital 1) and the signal provided at the second comparator output 105 will be low (e.g. a digital 0). Similarly, if the magnitude of the voltage received at the first input terminal 102 is smaller than the voltage received at the second input terminal 103 then the signal provided at the first comparator output 104 will be low (e.g. a digital 0) and the signal provided at the second comparator output 105 will be high (e.g. a digital 1). More generally, it will be appreciated that signals being high or low is arbitrary, i.e. it is equally possible for a low output to indicate a positive comparison or a negative comparison. Instead of referring to high/low or 1/0, the outputs may be referred to more generically as being set/reset.

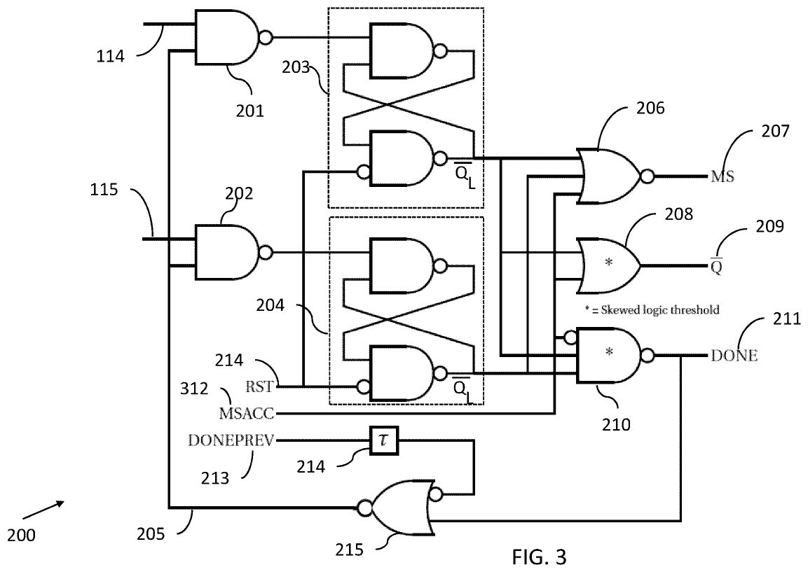

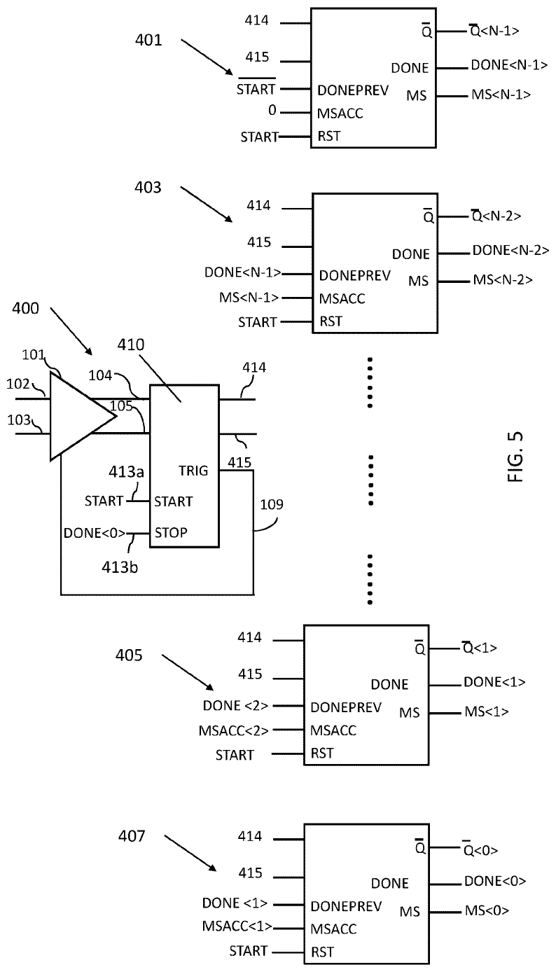

The first comparator output 104 of the comparator 101 is connected to a first OR gate 106. The output of the first OR gate 106 is provided to a first bit logic output terminal 114, as well as to a first input terminal of a four-input NOR gate 108. The second comparator output 105 of the comparator 101 is connected to a second OR gate 107. The output of the second OR gate 107 is provided to a second bit logic output terminal 115, as well as to a second input terminal of the four-input NOR gate 108. The bit logic output terminals 114 and 115 are connected to a plurality of bit logic circuits 200, described in more detail below with reference to FIGS. 3 and 5, which set the bit values for use in the SAR.

The four-input NOR gate 108 also includes a START signal input terminal 113a and a STOP signal input terminal 113b, used to control operation of the comparator circuit 100 by controlling the generation of a trigger signal TRIG when the comparator circuit 100 is active. When all of the inputs provided to the four-input NOR gate 108 are low, a high trigger signal TRIG is generated by the four-input NOR gate 108 which enables the comparator 101 to perform the next comparison. The output of the four-input NOR gate passes through a first delay element 110 before reaching the comparator 101. This delay allows time for the DAC (which provides one of the inputs to the comparator 101) to settle before the comparator 101 is triggered for the next comparison.

The output of the four-input NOR gate 108 remains low until at least one of its inputs goes high. In normal operation this should occur when the comparator 101 reaches a comparison decision and sets either its first comparator output 104 or its second comparator output 105 (depending on the result of the comparison) to a set state (high in this embodiment). These signals pass through the first and second OR gates 106, 107 and are connected to inputs of the four-input NOR gate 108. Therefore, as soon as the comparator 101 reaches a decision, the four-input NOR gate 108 changes its output to low and, after passing through first delay element 110, this low output on the TRIG line resets the comparator 101. Resetting the comparator 101 causes both the first comparator output 104 and the second comparator output 105 to be driven into the reset state (low in this embodiment). This in turn resets the inputs to the four-input NOR gate 108 to low so that the output of the four-input NOR gate 108 goes high again, which, after the delay element 101 triggers the next comparison to begin.

A timing circuit 109 is also arranged to to time out the comparator 101 in the event that a ‘TIMEOUT’ condition is reached, indicating that the comparator 101 is in a metastable state (i.e. that the voltages received at the first input terminal 102 and the second input terminal 103 are approximately equal).

The timing circuit 109 comprises an AND gate 112 arranged to receive at its two inputs the trigger signal from the output of the four-input NOR gate 108 and a delayed version of that trigger signal. The delay in this example is created by a first delay element 110 and a second delay element 111. This arrangement is convenient as it allows the delay of the first delay element 110 to be reused as part of the timing circuit 109. In other embodiments a single delay element could be used instead. In this embodiment, the second delay element 111 determines the predetermined time for timing out the comparator 101 as the trigger signal TRIG does not reach the comparator 101 until after the first delay element 110 (therefore it is only the additional delay of the second delay element 111 that determines the time limit on the comparator 101). However, connecting the first input of the AND gate 112 before the first delay element 110 (i.e. directly to the output of the four-input NOR gate 108) allows for a faster reset after a timeout occurs. The second delay element 111 may in some embodiments be variable so that the predetermined timeout period can be varied. Lengthening the delay of second delay element 111 will allow the comparator 101 more time to reach a decision, reducing the number of metastable timeouts, but increasing the overall maximum processing time for a complete cycle of the ADC.

The first delay element 110 is arranged to receive the output signal from the four-input NOR gate 108 and delay it for a first predetermined delay time τ₁ before passing it to the comparator 101 as the trigger signal. This ensures that enough time is provided between an output on terminals 114 and/or 115 and the next trigger signal reaching the comparator 101. This provides time for the DAC to settle after each change in DAC value, before the next comparison is performed by the comparator 101.

The output signal from the first delay element 110 is also provided to the second delay element 111. When this signal is received by the second delay element 111, it is delayed by a second predetermined delay time τ₂ that is used to time out the comparator 101 in the case of metastability. The second delay time τ₂ may be significantly longer than the first delay time τ₁, and is selected such that its duration is sufficiently long to be indicative of the comparator 101 being in a metastable state.

As the AND gate 112 receives the same signal at its inputs, but with the second input delayed relative to the first input, the AND gate 112 will output low unless the second (delayed) input goes high before the first (non-delayed) input goes low again. As the first input will go low as soon as the comparator reaches a decision, normal operation should result in the AND gate 112 never having high on both inputs. Therefore in normal operation the TIMEOUT signal 109b should remain low. This therefore has no effect, in normal operation, on the OR gates 106, 107 which simply pass through the comparator outputs 104, 105. However, if the comparator 101 is in a metastable state, it will not reach a decision before the second input of the AND gate 112 goes high. Now with two high inputs, the AND gate 112 outputs high. The output of AND gate 112 is passed to inputs of both the first OR gate 106 and the second OR gate 107 simultaneously. This overrides both the output on the first bit logic output terminal 114 and the second bit logic output terminal 115 to high. During normal operation, only one of these bit logic output terminals 114, 115 should be high, so this state (both high) indicates that a metastable state occurred.

As both the OR gates 106, 107 output high after the TIMEOUT signal 109b, the four-input OR gate 108 (which receives these at its inputs) immediately outputs low. This in turn resets the comparator 101 after the first delay time τ₁. It also immediately resets the TIMEOUT signal 109b which returns the outputs of NOR gates 106, 107 to low and initiates a trigger signal from the four-input NOR gate 108 to the comparator 101 to start the next comparison.

The bit logic output terminals 114, 115 provide their high and low signals to a plurality of bit logic circuits 200 for use in determination of the bit values for use in the SAR ADC. Each of these bit logic circuits 200 is triggered in turn as the comparator is reset. This process repeats until all of the bits of the SAR ADC have been determined

When every bit of the SAR ADC has been processed, or the comparator 101 enters a metastable condition, the STOP input terminal 113b of the four-input NOR gate 108 is set high, causing further comparisons by the circuit 100 to stop as all input terminals of the four-input NOR gate are prevented from going low simultaneously.

It will be appreciated that the embodiment shown in FIG. 2 has separate start and stop signals as inputs to the four-input NOR gate 108. This is a convenient arrangement that allows separate start and stop signals to be generated by different logic. However, in other embodiments a single start/stop input could achieve the same functionality by providing a low input to enable operation and a high input otherwise. This would then only require the OR gate 108 to be a three-input NOR gate 108. In yet other embodiments, the start and stop operations could be implemented separately from the NOR gate 108 and in those embodiments the NOR gate 108 could be a normal two-input NOR gate 108.

Having described how the bit logic output terminals 114 and 115 both output high signals in the event that the comparator 101 enters a metastable state, the use of these signals in determining the correct SAR ADC code with which the metastable state is associated will be described in the following with reference to FIGS. 3 to 6.

FIG. 3 shows a bit logic circuit 200 according to an embodiment of the present invention. Each bit logic circuit 200 is arranged to receive signals from the bit logic output terminals 114 and 115 and to provide a number of outputs, including a bit value for use in the SAR ADC based on those inputs. The bit logic circuit 200 shown in FIG. 3 is one of a plurality of bit logic circuits 200 arranged to work with the circuit 100 shown in FIG. 2, with one bit logic circuit 200 provided for each bit of the SAR ADC. Thus the bit logic output terminals 114, 115 are provided to all of the bit logic circuits 200. In the embodiments described here, the bit logic output terminals 114, 115 simply fan out to all bit logic circuits 200 simultaneously. In other embodiments a demultiplexer could connect the bit logic output terminals 114, 115 to the appropriate bit logic circuit 200.

Each bit logic circuit 200 is arranged to determine and output the state of its respective bit as it is determined, and once this has been completed, to enable the next bit logic circuit 200 in sequence to determine the next bit. Each bit logic circuit 200 is also configured to determine whether the comparator 101 enters a metastable state when determining its respective bit, and to output a metastability indication signal if so, as will be described in the following.

In operation, the bit logic circuit 200 receives a signal from the bit logic output terminals 114 and 115 output by the comparator circuit 100, and provides these to respective NAND gates 201 and 202. The NAND gates 201 and 202 are arranged to ensure that each bit logic circuit 200 is only active at the correct point in sequence, i.e. when the bit with which the bit logic circuit 200 is associated is to be determined. To achieve this, the NAND gates 201 and 202 also receive an enable signal 205, which is used to block further processing of the bit logic output terminals 114, 115 until the appropriate time.

The NAND gates 201 and 202 output to the ‘set’ input of respective latches 203 and 204. The latches are active low, meaning that they hold their state when both inputs are high and change state when one input goes low. The latches 203, 204 receive their ‘clear’ input from a reset signal RST 214. In this embodiment the reset inputs to the latches 203, 204 are inverted inputs so that when the reset signal is low, the latches 203, 204 have a high reset input. A high signal provided on the RST signal 214 will reset the latches at the beginning of each cycle. During operation of a bit logic circuit 200 (when the enable signal 205 is high), the signal at each of the bit logic output terminals 114 and 115 is initially low while the comparator 101 has not yet reached a decision. The output of both the NAND gates 201 and 202 (and thus the inputs to the set input of both of the latches 203 and 204) is high, and the input from the reset block 214 to the clear input of both of the latches 203 and 204 is low (inverted to high at the latch input). As such, in the initial state, both of the latches 203 and 204 have high set and high reset inputs and so will not change state. The latches 203, 204 thus remain in their reset state and output high at the Q̅_̅{̅L̅}̅ latch output.

When a signal from either of the bit logic output terminals (e.g. bit logic output terminal 115) transitions high, its respective NAND gate (e.g. NAND gate 201) outputs low to the ‘set’ input of its respective latch (e.g. latch 203). This causes the Q̅_̅{̅L̅}̅ output of the latch 203 to transition low. In normal operation, when the comparator has reached a decision without a timeout, the corresponding output of the other latch (e.g. latch 204) remains high.

The Q̅_̅{̅L̅}̅ output of the latches 203, 204 is provided to three logic gates 206, 208, 210, each configured to generate a respective output of the bit logic circuit 200, and to provide this at a respective output terminal 207, 209, 211.

Firstly, the Q̅_̅{̅L̅}̅ output of the latches 203, 204 is provided to a three-input NOR gate 206, arranged to check for metastability of the comparator 101. The three-input NOR gate 206 is arranged to drive the output MS of a metastability indication output terminal 207 high in the event that the Q̅_̅{̅L̅}̅ output of both of the latch circuits 203, 204 becomes low (which will only happen when both the bit logic output terminals 114, 115 are high). The three-input NOR gate 206 also receives an input from an accumulated metastability output (MSACC) 312, which is arranged to output low if the comparator 101 has not reached a metastable state in any preceding bits of the current ADC conversion cycle, but is arranged to output high if any preceding bit in the comparison in the current ADC conversion cycle reached a metastable state. Therefore the output MS bit 207 will be high only for the bit logic circuit 200 corresponding to the bit that first went metastable. All other bit logic circuits 200 will output the MS bit 207 low.

The pattern of signals output by the overall array of NOR gates 206 therefore employs a one-hot encoding to allow the metastable bit to be identified. For example, if the fourth bit of a sequence of eight bits is metastable, the output from the array of NOR gates 206 would be 00010000 where 1 indicates the metastable bit.

Secondly, the Q̅_̅{̅L̅}̅ output of the first latch 203 is also provided to an OR gate 208, used to generate an SAR signal Q̅ representative of the decision of the comparator and hence Q̅ gives the value of the bit determined by the bit logic circuit 200. The OR gate 208 receives the Q̅_̅{̅L̅}̅ output from the first latch 203, as well as the MSACC input signal 312. If the comparator 101 is not metastable, the Q̅ output 209 of the OR gate 208 tracks the Q̅_̅{̅L̅}̅ output of the first latch 203.

The first time that the comparator 101 becomes metastable in a conversion cycle, the MSACC input 312 will be low because no preceding bit in the cycle has reached a metastable state. The Q̅_̅{̅L̅}̅ output of latch 203 will be low as the input at bit logic output terminal 115 is high (because the metastable indication state has a high output on both terminals 114 and 115). Therefore the output at the Q̅ output 209 is low for the bit which reached a metastable state.

For all subsequent bits in the sequence of bit logic circuits 200 after a metastable state has been reached, the MSACC input 312 will be high and so the OR gate 208 is forced high and hence the Q̅ output 209 is forced high for all subsequent bits. Thus the metastable bit can also be identified in the array of Q̅ outputs by finding the least significant bit that is a ‘0’. For example, if the fourth bit of a sequence of eight bits is metastable, the output from the array of NOR gates 206 will be ???01111, allowing a determination to be made that the comparator became metastable at the last 0-valued bit. The ? symbol indicates bits whose state was correctly determined before metastability occurred and so these first three (most significant) bits may be either 0 or 1.

The OR gate 208 is a skewed gate, meaning that its input thresholds are skewed to require a more extreme than usual input in order to be treated as high or low. For example, a normal gate may treat any value above mid-voltage as high and any voltage below mid-voltage as low. A skewed gate may require a higher voltage, e.g. 80% of maximum to be received before it is considered a high input. In this embodiment the OR gate 208 is skewed towards the low extreme, i.e. a signal will only be treated as low when it falls to a low threshold (e.g. 20% of maximum). The reason for OR gate 208 to have skewed inputs is to avoid unpredictable behaviour from a slow latch 203. This can happen because the latch 203 itself can be in a metastable state if it receives a short input pulse on its set input. In such cases the latch 203 may output a mid-level voltage during a metastable period until it settles to one state or the other. This would in turn lead to an undefined Q output at 209. It is highly undesirable to have this output change after the bit logic circuit 200 is finished processing, so skewing the gate 208 ensures that the Q̅ output is well defined until the latch 203 has settled. Strictly, only the input of OR gate 208 that receives the Q̅_{L} output of latch 203 needs to be a skewed input. However, it will often be convenient to skew both inputs. MSACC should always be well-defined and settled, so skewing this input of OR gate 208 should have little effect.

Thirdly, the Q̅_{L} signals output by the latches 203, 204 are provided to two of the inputs of a three-input NAND gate 210 which is arranged to output a ‘DONE’ signal to a DONE terminal 211 once the value of the bit associated with the bit logic circuit 200 has been determined and provided at the Q̅ output terminal 209. The three-input NAND gate 210 also receives an input from the MSACC input 312. This input is inverted at the gate input such that when the MSACC input 312 is low (i.e. the comparator has not been in a metastable state for any preceding bits) the input received at the NAND gate 210 is high. When the MSACC input 312 is high (i.e. the comparator has previously been in a metastable state during the current conversion cycle) the input received at the NAND gate is low.

The three-input NAND gate 210 outputs low while MSACC 312 is low and the two Q̅_{L} outputs from latches 203, 204 are high. Any change to these inputs will result in a high output from NAND gate 210. At the start of processing of bit logic circuit 200, the bit logit output terminals 114, 115 will be low and the Q̅_{L} outputs of latches 203, 204 will be correspondingly high. If the comparator 101 provides an output, one of the bit logic output terminals 114 and 115 will be driven high, causing the Q̅_̅{̅L̅}̅ output of one of the latches 203, 204 to become low. Alternatively, if the comparator 101 does not reach a decision, both bit logic output terminals 114, 115 will go high and both Q̅_̅{̅L̅}̅ outputs from latches 203, 204 will go low. When this (or these) low Q̅_̅{̅L̅}̅ output is received at the three-input NAND gate 210, its three inputs differ, and the NAND gate output is driven high, causing a high ‘DONE’ signal to be asserted at the DONE output terminal 211, indicating that processing of this bit logic circuit 200 is completed. This DONE output 211 is also provided to a DONEPREV terminal 213 of the next bit logic circuit 200 in sequence indicating that the bit logic circuit 200 has output a value, and hence that the next bit logic circuit 200 in sequence may begin processing the next bit.

NAND gate 210 is also skewed, much like the OR gate 208 discussed above. This is also so that any temporary metastability in the latch circuits 203, 204 does not result in a DONE signal before the latches 203, 204 have settled. At least the two inputs of NAND gate 210 that come from the latches 203, 204 are skewed to require a strongly low signal in order to trigger the gate. The input from MSACC may also be skewed if convenient for design.

The DONE output from the three-input NAND gate 210 is also provided to a NOR gate 215 in order to generate the enable signal 205 which is provided to inputs of the NAND gates 201, 202 to ensure that the bit logic circuit 200 stops processing once DONE has been asserted. In other words, if DONE is triggered, then the bit logic circuit 200 stops and the process moves to the bit logic circuit 200 associated with the next bit in the sequence. The DONE signal is passed to the next bit logic circuit 200 as DONEPREV 213. When the DONEPREV signal is received at said next bit logic circuit 200, it passes through a delay element 214 with delay τ₃ before it is received at NOR gate 215 to enable the next bit logic circuit 200 to commence processing. The delay τ₃ ideally needs to be at least as long as the delay τ₁ to ensure that the signals at the bit logic output terminals 114 and 115 are low before the DONE signal is passed to the next bit logic 200 as DONEPREV 213.

In the case that the comparator 101 is metastable for a given bit, the Q̅_̅{̅L̅}̅ output of both of the latches 203, 204 of the bit logic circuit associated with that bit are driven low, which causes DONE to be asserted. After the comparator 101 enters a metastable state for a given bit, for all subsequent bits, the MSACC input 312 is high. The inverted input of the three-input NAND gate is therefore driven low, causing DONE to be asserted in all subsequent bit logic circuits 200 as soon as the MSACC output 312 becomes high. This allows the metastable state to be identified and processed as soon as possible, without any subsequent bits needing to be assessed by the comparator 101. Instead, the output of the succeeding bit logic circuits 200 is immediately output with Q̅ set low and DONE 211 is immediately asserted so that the conversion cycle is completed rapidly and without any more comparator delays. This ensures that the SAR ADC operates very fast upon entering a metastable state as all remaining bits are processed with minimum delay. This output also immediately provides an accurate digital representation of the input signal. The metastable state normally arises because the input voltage V_{IN} is so close to the DAC trial voltage that the comparator finds it hard to distinguish them. In this case, the DAC trial voltage may be considered as an accurate representation of the input voltage which should result in setting the current bit to a ‘1’ and all further bits to a ‘0’ (or, as the inverted output, Q̅ 209 is shown in FIG. 3, this bit is set to ‘0’ with all further bits set to ‘1’.

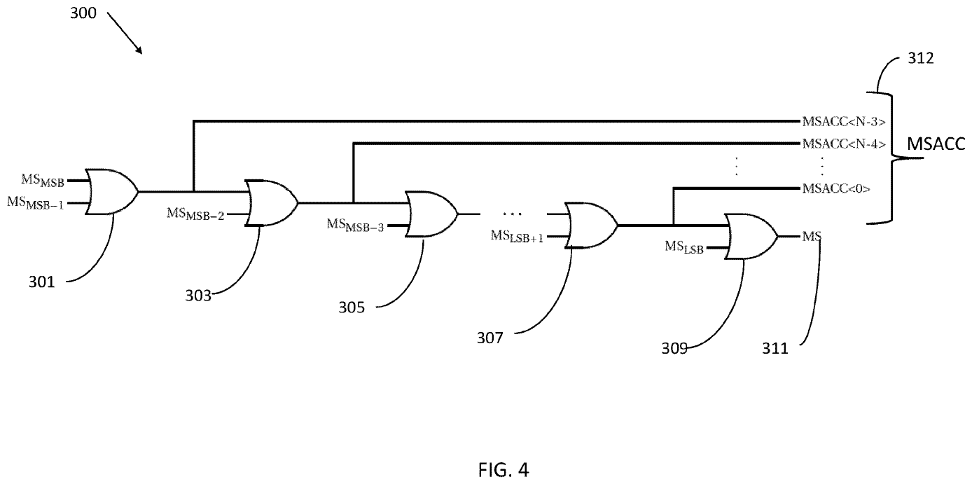

An example of a circuit 300 for generating the accumulated metastability inputs MSACC is shown in FIG. 4. The metastability indication output terminal 207 of each bit logic circuit 200 is provided to the accumulated metastability circuit 300. Each metastability output MS 207 from the various bit logic circuits 200 is represented in FIG. 4 with a subscript indicating which bit it came from, i.e. MS_{MSB} is the MS output 207 from the first bit logic circuit 200 which processes the most significant bit. MS_{MSB-1} is the MS output 207 from the second bit logic circuit 200 which processes the next most significant bit after the most significant bit, and so on.

As shown in FIG. 4, the accumulated metastability circuit 300 comprises a plurality of OR gates 301, 303, 305, 307, 309, each arranged to receive an input from the metastability indication output terminal 207 of a respective bit logic circuit 200.

The first OR gate 301 in the sequence receives inputs from the metastability output terminals 207 of the bit logic circuit associated with the most significant bit (MSB), and the second most significant bit (MSB−1). The second OR gate 303 in sequence receives an input from the output of the first OR gate 301, as well as from the metastability output terminal 207 of the bit logic circuit 200 of the third most significant bit (MSB−2). The third OR 305 gate in sequence receives an input from the output of the second OR gate 303, as well as from the metastability indication output terminal 207 of the bit logic circuit 200 of the fourth most significant bit (MSB−3), and so on. The final OR gate 309 receives an input from the previous OR gate 307, as well as from the metastability output terminal 207 of the bit logic circuit 200 of the least significant bit (LSB). The final OR gate 309 outputs its result to a global metastability output terminal 311, used to indicate to the SAR ADC that the comparator has entered a metastable state at some point in the conversion cycle.

Each OR gate 301-309 also outputs an accumulated metastability output (MSACC<0> to MSACC<N−3>) 312. These outputs 312 are each passed to the next bit logic circuit 200 as the MSACC input 312 for that bit logic circuit 200. For example, the MSACC<N−3> output provides the MSACC input 312 for the third bit logic circuit 200, the MSACC<N−4> output provides the MSACC input 312 for the fourth bit logic circuit 200 and the MSACC<0> output provides the MSACC input 312 for the last bit logic circuit 200. Each of these inputs indicates whether a metastable state has been reached in any bit logic circuit up to that point in the processing.

The link between the comparator circuit 100 and the bit logic circuits 200 is illustrated in FIG. 5, which shows a comparator circuit 400, being a generalised form of the comparator circuit 100, and N bit logic circuits, some of which are shown as 401, 403, 405, 407, each being a generalised form of the bit logic circuit 200 of FIG. 3 and each being associated with one of the N bits of the ADC output.

The logic block 410 of the comparator circuit 400 receives inputs from the first comparator output 104 and the second comparator output 105, as well as a START signal at input terminal 413a. As described above in relation to FIG. 2 (which shows one example of the logic block 410), the logic block 410 is arranged to generate a trigger signal TRIG which is provided to the comparator 101 to enable comparison, and the logic block 410 is arranged to provide high or low signals at the bit logic output terminals 414 and 415 for use by the plurality of bit logic circuits 401, 403, 405, 407.

It can also be seen in FIG. 5 that the logic block 410 is arranged to receive a signal at the STOP input terminal 413b in the form of a DONE<0> input, i.e. an input from the DONE output terminal 411 of the bit logic circuit 407 of the least significant bit LSB. As a result, when the least significant bit has been determined, or a metastable condition has been entered, causing all of the bit logic circuits to assert DONE, a STOP signal is received at the input 413b, preventing further operation of the comparator circuit 100 and hence the SAR ADC.

The signals at the bit logic output terminals 414 and 415 of logic block 410 are provided simultaneously to the input terminals of every bit logic circuit 401, 403, 405, 407 (at the inputs also labelled 414 and 415 for clarity). However, only one bit logic circuit 401, 403, 405, 407 will operate at a time. The bit logic circuit 401, 403, 405, 407 that operates is determined by the DONE signals.

In the embodiment shown in FIG. 5, the bit logic circuit 401 represents the most significant bit (MSB), i.e. the first bit to be processed in the SAR ADC conversion cycle. The bit logic circuit 403 represents the second most significant bit (MSB−1), i.e. the second bit to be processed in the SAR ADC conversion cycle. The bit logic circuit 405 represents the second least significant bit (LSB+1), i.e. the second last bit to be processed in the SAR ADC conversion cycle, and the bit logic circuit 407 represents the least significant bit (LSB), which is the last bit to be processed in the SAR ADC conversion cycle (completing the conversion).

It can be seen in FIG. 5 that in addition to receiving the signals from the bit logic output terminals 114 and 115, each bit logic circuit 401, 403, 405, 407 receives a DONEPREV input, an MSACC input, and a RST input. The DONEPREV input is the DONE output from the previous bit logic circuit, apart from the first bit logic circuit 401 which receives S̅T̅A̅R̅T̅ instead (as there is no previous circuit and it needs to receive a signal indicative of a DONE state). Thus, bit logic circuit 403 receives DONE<N−1>on its DONEPREV input, where DONE<N−1>is the DONE output from bit logic circuit 401. The MSACC input is the accumulated metastable state indicating whether any preceding bit has been in a metastable state. This may be generated by a circuit such as the one shown in FIG. 4. The first bit logic circuit 401 receives a ‘0’ at this input as there is no previous bit to have gone metastable. The second bit logic circuit 403 receives MS<N−1>from the first bit logic circuit 401 as this is the only metastable output to be accumulated. The third and subsequent bit logic circuits (of which the last two are shown at 405, 407) receive outputs from an array MSACC<N−3>to MSACC<0>(e.g. as shown in FIG. 4). The RST input of each bit logic circuit 401, 403, 405, 407 receives a reset signal that can reset any logic components that need resetting at the beginning of a conversion. In this embodiment, the START signal serves to provide the RST signal.

The bit logic circuits 401, 403, 405, 407 each output three signals, MS, DONE and Q̅. As described above in relation to the bit logic circuit 200 in FIG. 3, the MS signals together provide an array of N values MS<N−1>to MS<0>, each corresponding to one bit of the SAR ADC conversion and indicating which bit of the conversion reached a metastable state. The DONE signals together form an array of N values DONE<N−1>to DONE<0>indicating which bits have completed processing (although in this embodiment these values are only used internally and are not made available to subsequent circuits, in other embodiments, these signals could be made available). The Q̅ signals together form an array of N values Q̅<N−1>to Q̅<0>indicating the decisions reached by the comparator for each bit (or predefined values in the case of metastability) and which represent the ADC conversion. In this embodiment the Q̅ values are the inverse of the actual ADC conversion bit values, but in other embodiments the bit logic circuits could output the non-inverted values Q.

The array of bit values Q̅<N−1:0> is also used in the intermediate processing by the SAR ADC to generate the trial voltage to send to the comparator 101 for the next phase of the conversion cycle.

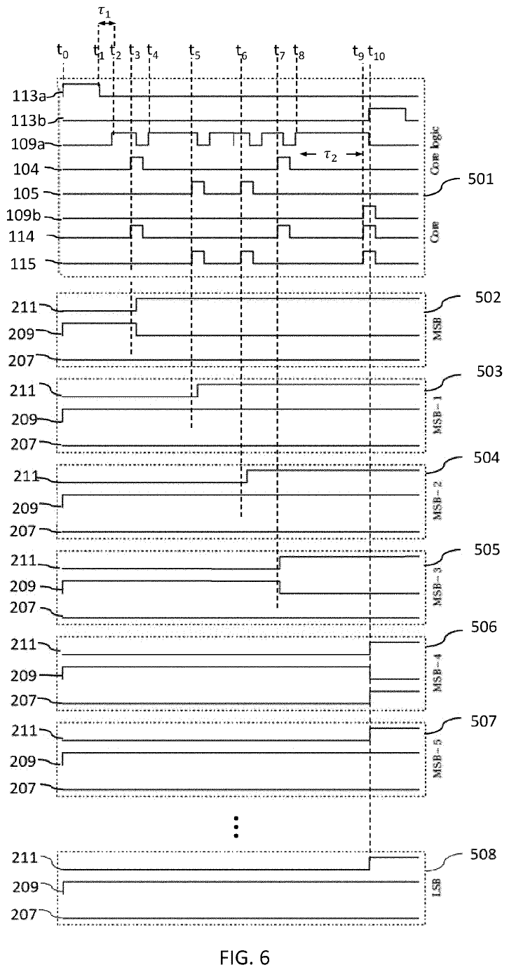

FIG. 6 shows a timing diagram illustrating the timing of various signals in the comparator circuit 100 and the bit logic circuits 200.

Box 501 of FIG. 6 illustrates the timing of signals in the comparator circuit 100 shown in FIG. 2 in operation. Initially, the first comparator output 104 and the second comparator output 105 of the comparator 101 are both low, as the comparator 101 is yet to receive a low START signal at the START input 113a. As a result, the first bit logic output terminal 114 and the second bit logic output terminal 115 are also low. As no trigger signal has been generated by the four-input NOR gate 108, the trigger signal 109a is low and the TIMEOUT signal 109b is also low.

At a time t₁, the START signal 113a of the four-input NOR gate 108 is set low. This causes the four-input NOR gate 108 to output high to the first delay element 110.

After a delay time τ₁, the first delay element 110 outputs a high trigger signal TRIG 109a at a time t₂. The trigger signal TRIG 109a is received by the comparator 101, which is then enabled and compares the voltages at its inputs 102 and 103. At a time t₃, the comparator 101 outputs a high signal, corresponding to the first bit (most significant bit), on the first comparator output 104. The high signal propagates through the first OR gate 106 to the first bit logic output terminal 114, which also outputs high at time t₃. The second comparator output 105 remains low, and as a result, the second bit logic output terminal 115 also remains low at time t₃. The first high signal output by the comparator 101 is passed from the first bit logic output terminal 114 to a first bit logic circuit 200 associated with the most significant bit MSB.

Block 502 shows the signals provided by the metastability output terminal MS 207, the SAR output terminal Q̅ 209 and the DONE output terminal 211 of the bit logic circuit 200 corresponding to the most significant bit MSB. It can be seen that initially, at t₀, the signals at the DONE output terminal 211 and the metastability output terminal MS 207 are both low, while the signal at the SAR output terminal Q̅ 209 is high, indicating that the output of the first latch 203 is high. Shortly after the first output of the comparator 101 at time t₃, the signal at the DONE output terminal 211 goes high, indicating that processing by the bit logic circuit 200 is complete, while the signal at the SAR output terminal Q̅ 209 goes low, indicating that the voltage at the first input 102 of the comparator 101 was greater than the voltage at the second input 103. After DONE is asserted on the bit logic circuit 200 corresponding to the MSB, the bit logic circuit 200 corresponding to the second most significant bit (i.e. MSB−1) is enabled, after a delay τ₃ to receive signals from the first bit logic output terminal 114 and the second bit logic output terminal 115.

Returning to block 501 at time t₃, the high signal on the first comparator output 104 is propagated via the first OR gate 106 to the four-input NOR gate 108, causing the four-input NOR gate 108 to output low. This low signal feeds through to the comparator 101 via the first delay element 110, resetting its outputs 104, 105 to low. This in turn is propagated via the first and second OR gates 106 and 107 to the four-input NOR gate 108, causing the four-input NOR gate 108 to output high. The high signal from the four-input NOR gate 108 causes a high trigger signal TRIG 109a at a time t₄, which is received by the comparator 101. The comparator 101 then performs another comparison and this time it outputs a high signal on the second comparator output 105 at a time t₅. The high signal propagates through the second OR gate 107 to the second bit logic output terminal 115, which also outputs high at time t₅. The first comparator output 104 remains low, and as a result, the first bit logic output terminal 114 also remains low at time t₅. This second high signal output by the comparator 101 is passed to a second bit logic circuit 200 associated with the second most significant bit MSB−1.

Block 503 shows the signals on the metastability output terminal MS 207, the SAR output terminal Q̅ 209 and the DONE output terminal 211 of the bit logic circuit 200 corresponding to the second significant bit MSB−1. It can be seen that initially, at to, the signal at the DONE output terminal 211 and the metastability output terminal MS 207 are both low, while the signal at the SAR output terminal Q̅ 209 is high, indicating that the output of the first latch 203 is high. Shortly after the second output of the comparator at time t₅, the signal at the DONE output terminal 211 goes high, indicating that processing by the bit logic circuit 200 is complete, while the signal at the SAR output terminal Q̅ 209 remains high, indicating that the voltage at the first input 102 of the comparator 101 was smaller than the voltage at the second input 103. After DONE is asserted on the bit logic circuit 200 corresponding to MSB−1, the bit logic circuit 200 corresponding to the third most significant bit MSB−2 is enabled, after a delay τ₃ to receive signals from the first bit logic output terminal 114 and the second bit logic output terminal 115.

After time t₅, the process described above repeats and the comparator 101 outputs a third high signal on the second comparator output 105 at a time t₆, corresponding to the third most significant bit MSB−2, which is processed by a third bit logic circuit 200 as illustrated in block 504 of FIG. 6. This is followed by a fourth output signal on the first comparator output 104 of the comparator 101 at a time t₇, corresponding to the fourth most significant bit MSB−3, which is processed by a fourth bit logic circuit 200 as illustrated in block 505 of FIG. 6.

The high signal at time t₇ causes a high trigger signal TRIG 109a at a time t₈ which is received by the comparator 101. Comparator 101 then begins comparing inputs relating to the fifth most significant bit MSB−4. However, the comparator 101 fails to output a result within a TIMEOUT duration τ₂, causing the second delay element 111 to output high to the AND gate 112, while the output of the four-input NOR gate 108 is also high. This causes the AND gate 112 to provide a timeout signal 109b which becomes high at a time t₉. This timeout signal 109b provides a high input to the first OR gate 106 and the second OR gate 107 simultaneously, indicating that the comparator 101 is in a metastable state. The two high signals output by OR gates 106 and 107 cause high signals to be output at the first bit logic output terminal 114 and the second bit logic output terminal 115, from which they are provided to the bit logic circuit 200 associated with the fifth most significant bit MSB−4 as illustrated in block 506 of FIG. 6.

Block 506 shows the signals on the metastability output terminal MS 207, the SAR output terminal Q̅ 209 and the DONE output terminal 211 of the bit logic circuit corresponding to the fifth most significant bit MSB−4. It can be seen that initially, at t₀, the signal at the DONE output terminal 211 and the metastability output terminal MS 207 are both low, while the signal at the SAR output terminal Q̅ 209 is high, indicating that the output of the first latch 203 is high. Shortly after the timeout signal 109b is generated at t₉, the signal at the DONE output terminal 211 of the fifth most significant bit MSB−5 goes high at a time t₁₀, indicating that processing by the bit logic circuit 200 is complete. The signal at the SAR output terminal Q̅ 209 goes low, as the output of the first latch switches from high to low. The signal at the metastability output terminal MS 207 also goes high at time t₁₀, indicating that the comparator 101 is in a metastable state.

As the metastability terminal MS 207 goes high, the OR gate of the accumulated metastability circuit 300 (shown in FIG. 4) corresponding to the fifth most significant bit MSB−4 also goes high, causing the MSACC output (MSACC) 312 to go high on all of the remaining bit logic circuits 200 in sequence. As a result, DONE is asserted in all remaining bit logic circuits 200 in rapid succession (only delayed by τ₃), while the signal at the SAR output terminal Q̅ 209 is set high for all remaining bit logic circuits 200 and the signal at the metastability output terminal MS 207 is set low for all remaining bit logic circuits. This is illustrated in blocks 507 and 508 of FIG. 6.

Block 507 shows signals in the bit logic circuit 200 associated with the sixth most significant bit MSB−5, i.e. the bit logic circuit corresponding to the bit immediately after the metastable bit MSB−4 described above. Block 507 shows the signals on the metastability output terminal MS 207, the SAR output terminal Q̅ 209 and the DONE output terminal 211 of the bit logic circuit corresponding to the sixth most significant bit MSB−5. It can be seen that initially, at t₀, the signals at the DONE output terminal 211 and the metastability output terminal MS 207 are both low, while the signal at the SAR output terminal Q̅ 209 is high, indicating that the output of the first latch 203 is high. However, as soon as the signal at the metastability output terminal MS 207 of the bit logic circuit 200 associated with the previous metastable bit, i.e. MSB−4, goes high at t₁₀, the signal at the DONE output terminal 211 of the bit logic circuit 200 associated with MSB−5 goes high, indicating that processing by the corresponding bit logic circuit 200 is complete. The signal at the SAR output terminal Q̅ 209 remains high and the metastability output terminal MS 207 remains low in order to allow the metastable bit to be identified as described earlier in the application.

Block 508 shows signals in the bit logic circuit 200 associated with the least significant bit LSB. Block 507 shows the signals on the metastability output terminal MS 207, the SAR output terminal Q̅ 209 and the DONE output terminal 211 of the bit logic circuit 200 corresponding to the LSB. It can be seen that initially, at t₀, the signal at the DONE output terminal 211 and the metastability output terminal MS 207 are both low, while the signal at the SAR output terminal Q̅ 209 is high, indicating that the output of the first latch 203 is high. However, as soon as the signal at the metastability output terminal MS 207 of the bit logic circuit 200 associated with the previous metastable bit, i.e. LSB+1, goes high at t₁₀, the DONE output terminal 211 of the bit logic circuit associated with the LSB goes high, indicating that processing by the bit logic circuit 200 associated with the LSB is complete. The signal at the SAR output terminal Q̅ 209 remains high and the metastability output terminal MS 207 remains low, in order to allow the metastable bit to be identified as described earlier in the application.

Returning to block 501 shortly after time t₉, when the rapid processing of the remaining bit logic circuits 200 has been completed, the DONE output 211 from the bit logic circuit 200 associated with the LSB provides a STOP signal at the input 113b of the four-input NOR gate 108, preventing further action by the comparator circuit 100. This completes the SAR ADC conversion cycle.

Thus, as can be seen in FIG. 6, the comparator circuit 100 and the plurality of bit logic circuits 200 serve to provide outputs for a SAR ADC indicating the value to which each bit should be set, while allowing metastability of the comparator 101 to be detected and preventing the metastable state of the comparator from delaying processing and slowing down the ADC. In the event that the comparator 101 becomes metastable, the comparator circuit 100 and the bit logic circuits 200 are able to identify the metastable bit through the outputs at the metastability output terminals MS 207, and to prevent further unnecessary processing by asserting DONE in all remaining bit logic circuits 200, and outputting a STOP signal in the comparator circuit 100.

It will be appreciated by those skilled in the art that the invention has been illustrated by describing one or more specific embodiments thereof, but is not limited to these embodiments; many variations and modifications are possible, within the scope of the accompanying claims.

1. A circuit for detecting metastability in an asynchronous successive approximation register analogue to digital converter; the circuit comprising:
a two-output comparator;
control logic;
a first output terminal; and
a second output terminal;
wherein the two-output comparator is arranged to receive first and second input signals;
wherein the two-output comparator is arranged to:
receive a trigger signal from the control logic;
based on the receipt of the trigger signal:
set a first comparison signal and a second comparison signal to a reset state;
compare the first input signal with the second input signal; and
drive one of the first and second comparison signals to a set state based on the comparison;
wherein the control logic is configured such that:
the first output terminal is in a set state when the first comparison signal is in a set state;
the second output terminal is in a set state when the second comparison signal is in a set state; and
if a predetermined duration passes after the start of the comparison by the two-output comparator and if the first comparison signal and the second comparison signal are both in the reset state, the control logic outputs a set state at both the first output terminal and the second output terminal.

2. A circuit as claimed in claim 1, wherein if the control logic outputs a set state on both the first output terminal and the second output terminal, the circuit is configured to output a signal representative of the two-output comparator being in a metastable state.

3. A circuit as claimed in claim 1, wherein the control logic is configured to provide the trigger signal to the two-output comparator based on the comparator driving one of the first and second comparison signals to a set state.

4. A circuit as claimed in claim 3, wherein the control logic comprises a first delay element, and wherein the first delay element is configured to delay the sending of the trigger signal to the two-output comparator by a second predetermined duration.

5. A circuit as claimed in claim 1, wherein the first output terminal and the second output terminal are connected to a plurality of bit logic circuits, wherein each bit logic circuit is configured to determine a bit value based on the state of the first and second output terminals.

6. A circuit as claimed in claim 5, wherein each bit logic circuit is configured to determine its respective bit value following receipt of a respective trigger signal at the two-output comparator.

7. A circuit as claimed in claim 5, wherein the bit logic circuits are configured to determine their respective bit values in sequence.

8. A circuit as claimed in claim 7, wherein when a bit logic circuit of the plurality of bit logic circuits determines a bit value, said bit logic circuit also outputs a completion signal indicating that a bit value has been determined for that bit logic circuit.

9. A circuit as claimed in claim 8, wherein the completion signal is provided to the next bit logic circuit in sequence, and wherein said next bit logic circuit is configured to determine its respective bit value upon receipt of the completion signal.

10. A circuit as claimed in claim 5, wherein if the control logic outputs a set state on both the first output terminal and the second output terminal following receipt of a trigger signal at the two-output comparator, the respective bit logic circuit is configured to output a signal representative of the two-output comparator being in a metastable state.

11. A circuit as claimed in claim 10, wherein the signal representative of the two-output comparator being in a metastable state is provided to a global metastability detection circuit.

12. A circuit as claimed in claim 11, wherein the global metastability detection circuit comprises a chain of OR gates; wherein each OR gate is arranged to receive a first input from a respective bit logic circuit, and a second input from a previous OR gate in the chain of OR gates.

13. A circuit as claimed in claim 12, wherein each OR gate of the global metastability detection circuit is configured to output an accumulated metastability detection signal.

14. A circuit as claimed in claim 5, wherein each bit logic circuit is arranged to receive an accumulated metastability input and wherein upon receipt of an accumulated metastability signal at the accumulated metastability input, the bit logic circuit outputs a predetermined bit value and outputs a completion signal indicating that a bit value has been determined.

15. A circuit as claimed in claim 5, wherein each bit logic circuit is configured to determine its respective bit value as high if the first output terminal is in a set state and the second output terminal is in a reset state, and to determine its respective bit value as low if the first output terminal is in a reset state and the second output terminal is in a set state.

16. A circuit as claimed in claim 5, wherein each bit logic circuit is arranged to determine its respective bit value to be high if the first output terminal is in a set state and the second output terminal is in a set state.

17. A circuit as claimed in claim 15, wherein each bit logic circuit outputs the respective determined bit value to a digital to analogue converter.

18. A circuit as claimed in claim 1, wherein the control logic comprises a first OR gate arranged to receive the first comparison signal and a second OR gate arranged to receive the second comparison signal.

19. A circuit as claimed in claim 18, wherein the first OR gate and the second OR gate provide output signals to the first output terminal and the second output terminal.

20. A circuit as claimed in claim 18, wherein the control logic comprises a NOR gate arranged to receive an input signal from the output of the first OR gate and an input signal from the output of the second OR gate.

21. A circuit as claimed in claim 20, further comprising an AND gate having a first input and a second input, the first input and the second input each arranged to receive an output of the NOR gate, wherein the second input is delayed relative to the first input.

22. A circuit as claimed in claim 21, wherein the output of the AND gate is provided to an input of the first OR gate and to an input of the second OR gate.

23. A circuit as claimed in claim 20, wherein the output of the NOR gate is provided to the two-output comparator as the trigger signal.

24. A circuit as claimed in claim 23, wherein the output of the NOR gate is delayed by a delay element defining a second predetermined duration.

25. A method of detecting metastability in an asynchronous successive approximation register analogue to digital converter; the method comprising:
receiving, at a two-input comparator, a first input signal and a second input signal,
receiving, at the two-input comparator, a trigger signal;
based on the trigger signal:
setting a first comparison signal and a second comparison signal to a reset state;
comparing the first input signal and the second input signal; and
driving one of the first and second comparison signals to a set state based on the the method further comprising:
outputting a set state at a first output terminal when the first comparison signal is in a set state;
outputting a set state at a second output terminal when the second comparison signal is in a set state; and
outputting a set state at the first output terminal and the second output terminal if a predetermined duration passes after starting the comparison and if the first comparison signal and the second comparison signal are both in the reset state.
